(19) United States
(12) Patent Application Publication
(10) Pub. No.: US 2008/0017977 A1
(43) Pub. Date: Jan. 24, 2008

(54) Heat dissipating semiconductor package and heat dissipating structure thereof

(75) Inventors: Wen-Tsung Tseng, Taichung (TW); Chien-Ping Huang, Hsinchu Hsein (TW); Ho-Yi Tsai, Taichung Hsien (TW); Cheng-Hsu Hsiao, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/801,625

(22) Filed: May 10, 2007

(30) Foreign Application Priority Data
Jul. 21, 2006 (TW) 095126659

(51) Int. Cl. H01L 23/34

(52) U.S. Cl. 257/712; 257/E23.08

(57) ABSTRACT

A heat dissipating semiconductor package and a heat dissipating structure thereof are provided. The heat dissipating structure includes an outer surface, consecutive recessed step portions, and a pressure-releasing groove. The outer surface is exposed from an encapsulant made of a molding compound. The step portions are formed at an edge of the outer surface and have decreasing depths wherein the closer a step portion to a central position of the outer surface, the smaller the depth of this step portion is. The pressure-releasing groove is disposed next to and deeper than the innermost one of the step portions. A molding compound flows to the step portions and absorbs heat from an encapsulation mold quickly, such that a flowing speed of the molding compound is reduced. Pressure suffered by air remaining at the step portions is released through the pressure-releasing groove, thereby preventing flashes of the molding compound and resin bleeding.

### FIELD OF THE INVENTION

The present invention relates to semiconductor packages and, more particularly, to a heat dissipating structure for a semiconductor package, and a heat dissipating semiconductor package integrated with the heat dissipating structure.

### BACKGROUND OF THE INVENTION

Semiconductor packages with reduced integrated circuit (IC) areas and densely arranged contacts, such as Ball Grid Array (BGA) packages, have become the mainstream package products in response to the demand for compact electronic devices. Such semiconductor packages with densely packed electronic circuits and electronic components generate much heat during operation, and semiconductor chips mounted in the semiconductor packages are typically encapsulated by encapsulants having poor thermal conductivity. As a result, the semiconductor packages do not have a satisfactory heat dissipating efficiency to effectively dissipate the heat generated during operation, thereby adversely affecting the performance of the semiconductor chips. Accordingly, incorporation of a heat sink into a semiconductor package has been proposed to improve the heat dissipating efficiency of the semiconductor package. The heat sink is exposed from the encapsulant so as to effectively dissipate heat generated by a semiconductor chip in the semiconductor package. Related prior arts include U.S. Pat. Nos. 6,552,428 and 5,851,337.

FIG. 1 shows a conventional semiconductor package integrated with a heat sink. In this semiconductor package, the heat sink 11 is disposed on a substrate 12 and is held above a semiconductor chip 10, wherein a top surface 110 of the heat sink 11 is exposed from an encapsulant 13, such that heat generated by the semiconductor chip 10 during operation can be dissipated through the heat sink 11.

The above semiconductor package however has some significant drawbacks relating to its fabrication processes. For example, in order to expose the top surface 110 of the heat sink 11 from the encapsulant 13, it is necessary to allow the top surface 110 of the heat sink 11 to abut against a top wall of a mold cavity of an encapsulation mold (not shown) during a molding process for forming the encapsulant 13. However, in practice, due to great mold flow pressure, the encapsulant 13 may flash onto the top surface 110 of the heat sink 11 (as shown in FIG. 2), thereby undesirably affecting the heat dissipating efficiency of the heat sink 11 and the appearance of the finished product. Thus, a deflash process is usually required to remove the flashes of the encapsulant 13. However, the deflash process is time-consuming and cost-ineffective, and also tends to cause damage to the finished product.

In view of the aforesaid drawbacks, U.S. Pat. No. 6,188,130 discloses a heat sink 21 with a flange 210 formed on a top surface thereof, as shown in FIG. 3. This heat sink 21 can have an increased sealing pressure with an encapsulation mold 24 due to a reduced contact area between the heat sink 21 and the encapsulation mold 24 provided by the flange 210, so as to prevent an encapsulant 23 from flashing onto the top surface of the heat sink 21.

Although the aforesaid method is effective in preventing the flashes of the encapsulant, since the encapsulant is typically composed of fillers and a resin having excellent fluidity in a liquid state, the resin would easily leak beyond the flange of the heat sink, thereby resulting in translucent resin bleeding and degrading the heat dissipation performance of the heat sink.

Accordingly, as shown in FIG. 4, U.S. Pat. No. 6,249,433 to the same assignee as the present invention, discloses a heat sink 31 having a top surface 310 formed with a stepped structure 312, wherein the stepped structure 312 comprises a plurality of steps having decreasing depths. By this arrangement, when a molding compound for forming an encapsulant 33 flows onto the top surface 310 of the heat sink 31, it would absorb heat more quickly due to the stepped structure 312 and thus becomes more viscous such that the molding compound slows down its flowing speed and flashes of the encapsulant 33 can be effectively controlled.

With the advances in material and semiconductor technologies, there are developed fine fillers having a size of about 25 μm smaller than the size (about 50 μm) of the conventional fillers and a resin having better fluidity. A molding compound composed of the fine fillers and the highly fluid resin can form an encapsulant without damaging bonding wires that electrically couple a wire-bonded chip to a substrate and without the occurrence of sagging, shifting and short-circuiting of the bonding wires, and even may directly fill a space between a flip chip and a substrate and encapsulate conductive bumps disposed in the space.

For the aforesaid semiconductor package having the heat sink 31 formed with the stepped structure 312, when the top surface 310 of the heat sink 31 abuts against a top wall of a mold cavity of an encapsulation mold 34 and the molding compound injected into the mold cavity flows to the stepped structure 312 during a molding process, air 35 remaining at the stepped structure 312 cannot escape and is thus compressed by the molding compound (as shown in FIG. 5A). When the air 35 keeps being compressed and reaches the last step (i.e. the step having the smallest depth) of the stepped structure 312, it is subjected to maximum pressure and is thereby squeezed into a seam between the heat sink 31 and the encapsulation mold 34 to form a gap 36 (as shown in FIG. 5B). This makes the resin of the molding compound introduced into the gap 36 between the heat sink 31 and the encapsulation mold 34 along with the compressed air 35, thereby resulting in resin bleeding. FIG. 5C is a real partial top view of the heat sink, showing that resin bleeding G occurs on the top surface of the heat sink exposed from the encapsulant. This problem is particularly severe in the case of using a molding compound comprising fine fillers, and accordingly the last step of the stepped structure is made extremely shallow, for example having a depth of 0.01 to 0.03 mm. Such extremely shallow step makes air at the stepped structure suffer very large compression pressure, and as a result, the gap 36 between the heat sink 31 and the encapsulation mold 34 is more easily formed, and flashes of the encapsulant 33 and resin bleeding more easily occur.

Therefore, the problem to be solved here is to provide a semiconductor package with a heat sink, without encountering the problems of encapsulant flashes and resin bleeding especially when using a molding compound comprising fine fillers and a highly fluid resin in a molding process.

### SUMMARY OF THE INVENTION

In view of the aforesaid drawbacks of the prior art, a primary objective of the present invention is to provide a heat dissipating semiconductor package and a heat dissipating structure thereof, so as to prevent encapsulant flashes and resin bleeding during a molding process performed to form the semiconductor package.

Another objective of the present invention is to provide a heat dissipating semiconductor package and a heat dissipating structure thereof, so as to prevent flashes of a molding compound and resin bleeding that occur conventionally in the case of using the molding compound composed of fine fillers and a highly fluid resin.

A further objective of the present invention is to provide a heat dissipating semiconductor package and a heat dissipating structure thereof, so as to prevent flashes of a molding compound and resin bleeding that occur conventionally in the case of using a heat sink formed with a stepped structure.

In order to achieve the above and other objectives, the present invention discloses a heat dissipating structure for a semiconductor package. The heat dissipating structure comprises: a heat dissipating body having an outer surface exposed from an encapsulant that encapsulates a semiconductor chip in the semiconductor package; a plurality of consecutive recessed step portions formed at an edge of the outer surface of the heat dissipating body, and having decreasing depths in a manner that the closer a step portion to a central position of the outer surface of the heat dissipating body, the smaller the depth of this step portion is; and a pressure-releasing groove disposed next to and deeper than an innermost one of the step portions which is closest to the central position of the outer surface of the heat dissipating body. The heat dissipating body is made of metal having good thermal conductivity. The pressure-releasing groove is 1.5 to 4 times, preferably 1.5 times, deeper than the innermost one of the step portion, so as to release pressure suffered by air remaining at the step portions.

The present invention also discloses a semiconductor package with the heat dissipating structure. In a preferred embodiment, the semiconductor package comprises: a substrate; at least one semiconductor chip mounted on and electrically connected to the substrate; and a heat dissipating structure mounted on the substrate, the heat dissipating structure comprising a heat dissipating body having an outer surface, and a supporting portion integrally formed with the heat dissipating body to hold the heat dissipating body above the semiconductor chip, the heat dissipating structure further comprising a plurality of consecutive recessed step portions and a pressure-releasing groove, wherein the outer surface is exposed from an encapsulant that encapsulates the semiconductor chip, a portion of the substrate and a portion of the heat dissipating structure, the step portions are formed at an edge of the outer surface and have decreasing depths in a manner that the closer a step portion to a central position of the outer surface of the heat dissipating body, the smaller the depth of this step portion is, and the pressure-releasing groove is disposed next to and deeper than an innermost one of the step portions which is closest to the central position of the outer surface.

In another preferred embodiment, the semiconductor package comprises: at least one semiconductor chip; a plurality of leads electrically connected to the semiconductor chip; and a heat dissipating structure attached to the semiconductor chip, the heat dissipating structure comprising an outer surface, a plurality of consecutive recessed step portions and a pressure-releasing groove, wherein the outer surface is exposed from an encapsulant that encapsulates the semiconductor chip, a portion of the heat dissipating structure and portions of the leads, the steps portions are formed at an edge of the outer surface and have decreasing depths in a manner that the closer a step portion to a central position of the outer surface of the heat dissipating body, the smaller the depth of this step portion is, and the pressure-releasing groove is disposed next to and deeper than an innermost one of the step portions which is closest to the central position of the outer surface. Alternatively, the semiconductor chip can be mounted on a die pad that is attached to the heat dissipating structure.

Therefore, by the semiconductor package and the heat dissipating structure thereof according to the present invention, there are at least two consecutive recessed step portions formed at an edge of an outer surface of a heat dissipating body of the heat dissipating structure, wherein the step portions together form a stepped structure and have decreasing depths measured from the outer surface of the heat dissipating body. The closer the step portion to the central position of the outer surface, the smaller the depth of this step portion is. During a molding process, when a molding compound for forming an encapsulant flows to the step portions of the heat dissipating structure, the molding compound absorbs heat from an encapsulation mold rapidly due to the decreasing depths of the step portions, such that viscosity of the molding compound is increased and the flowing speed thereof is reduced. When the molding compound reaches the innermost step portion, its flowing speed is sufficiently reduced. A pressure-releasing groove is located next to and deeper than the innermost step portion, such that when the molding compound flows to the step portions and compresses air remaining at the step portions, the compressed air reaches the relatively deeper pressure-releasing groove where great pressure suffered by the air can be released rapidly, thereby not making the air squeezed into any seam between the heat dissipating structure and the encapsulation mold. As a result, flashes of the molding compound and resin bleeding are both prevented.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a conventional semiconductor package integrated with a heat sink;

FIG. 2 (PRIOR ART) is a schematic diagram showing an encapsulant flashing onto a top surface of the heat sink;

FIG. 3 (PRIOR ART) is a cross-sectional view of a semiconductor package with a heat sink wherein the heat sink comprises a flange formed on a top surface thereof, as disclosed in U.S. Pat. No. 6,188,130;

FIG. 4 (PRIOR ART) is a cross-sectional view of a semiconductor package with a heat sink wherein the heat sink is formed with a stepped structure on a top surface thereof, as disclosed in U.S. Pat. No. 6,249,433;

FIGS. 5A, 5B and 5C (PRIOR ART) are schematic diagrams and a real partial top view (photo) showing flashes of an encapsulant and resin bleeding on the top surface of the heat sink as disclosed in U.S. Pat. No. 6,249,433;

FIG. 6A is a cross-sectional view of a heat dissipating structure for a semiconductor package in accordance with the present invention;

FIG. 6B is a cross-sectional view showing a molding compound flowing to the heat dissipating structure in accordance with the present invention;

FIG. 7A is a cross-sectional view of a heat dissipating semiconductor package in accordance with a first embodiment of the present invention;

FIG. 7B is a real partial top view (photo) of a heat dissipating structure of the heat dissipating semiconductor package in accordance with the present invention;

FIG. 8 is a cross-sectional view of a heat dissipating semiconductor package in accordance with a second embodiment of the present invention; and

FIG. 9 is a cross-sectional view of a heat dissipating semiconductor package in accordance with a third embodiment of the present invention.

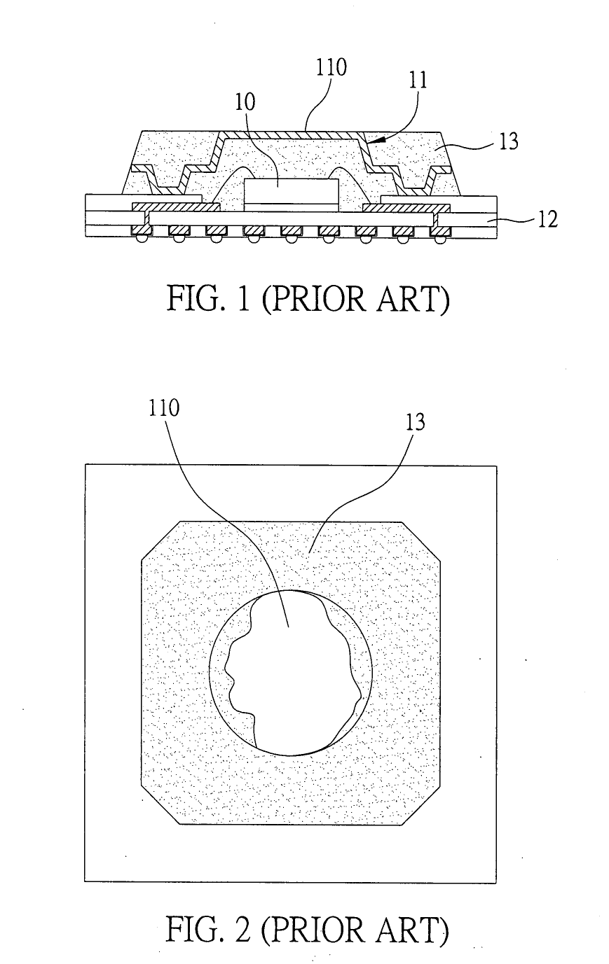

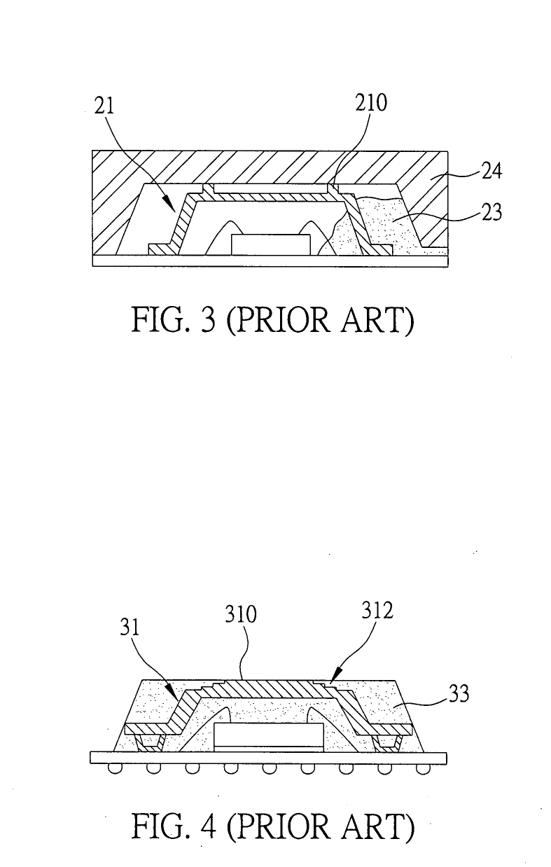

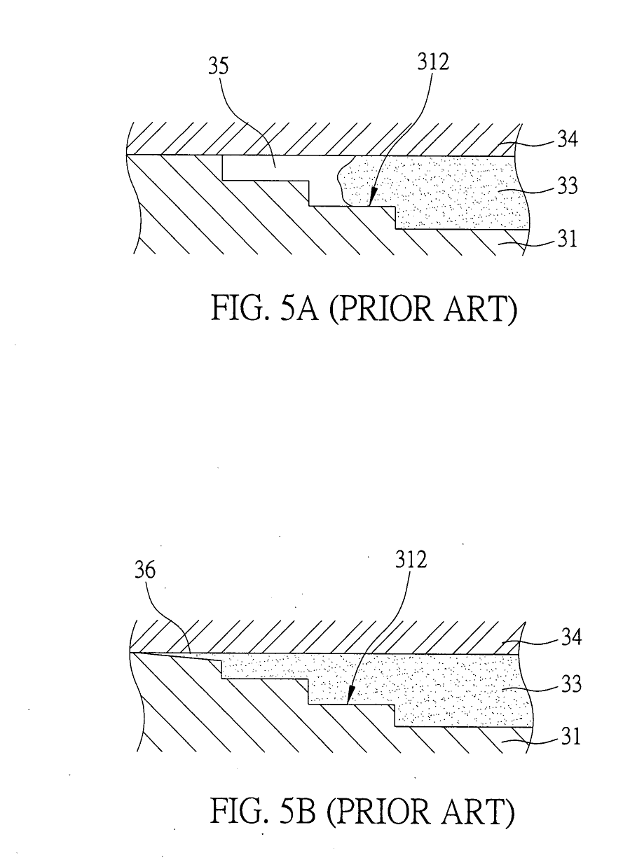

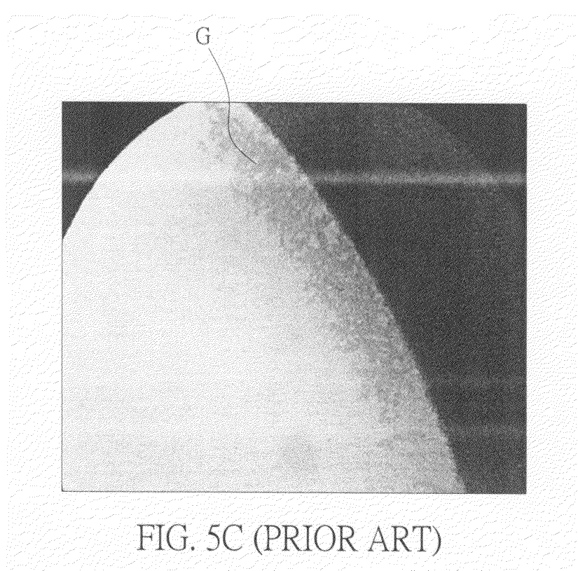

### DETAILED DESCRIPTION OF THE PREFERRED EMBODIMENTS

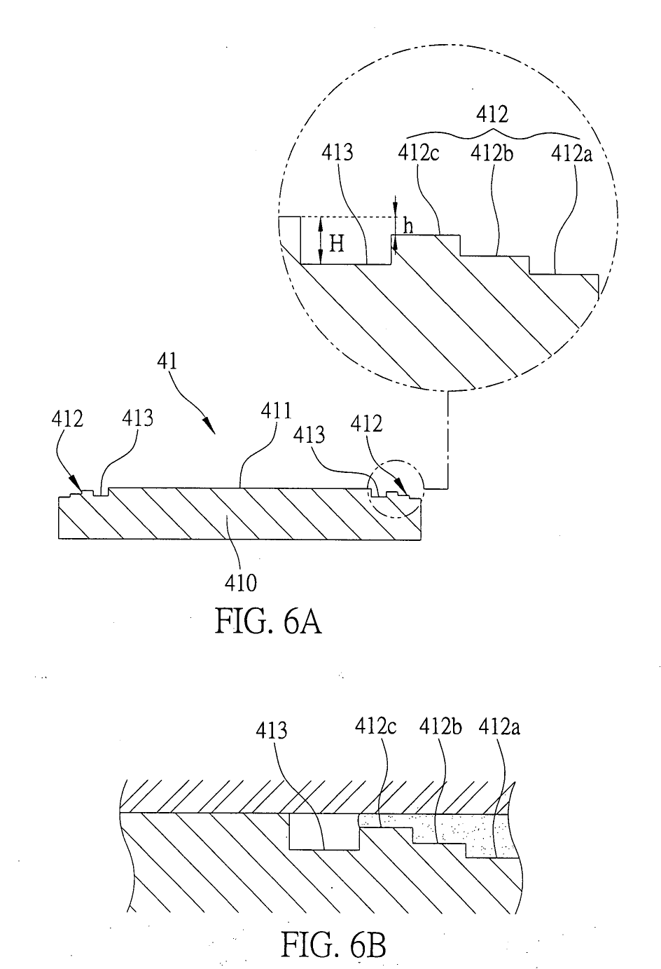

Preferred embodiments of a heat dissipating semiconductor packages and a heat dissipating structure thereof as proposed in the present invention are described as follows with reference to FIGS. 6 to 9. It should be understood that the drawings are simplified schematic diagrams only showing the elements relevant to the present invention, and the layout of elements could be more complicated in practical implementation.

FIGS. 6A and 6B show a heat dissipating structure 41 of the present invention. The heat dissipating structure 41 comprises a plate-shaped heat dissipating body 410 made of a metal having high thermal conductivity, such as copper, aluminum, etc. The heat dissipating body 410 comprises an outer surface 411 exposed from an encapsulant that is used for encapsulating a semiconductor chip of a semiconductor package (to be described later). A stepped structure 412 is formed at an edge of the outer surface 411 of the heat dissipating body 410, and comprises at least three consecutive recessed step portions, including a first step portion 412a, a second step portion 412b, and a third step portion 412c, which in such order are located at positions getting closer to a central position of the outer surface 411 and have decreasing depths measured from the outer surface 411, wherein the first step portion 412a is made deeper than the second step portion 412b, and the second step portion 412b is made deeper than the third step portion 412c. A pressure-releasing groove 413 is disposed adjacent to the innermost step portion of the stepped structure 412 (i.e. the third step portion 412c closest to the central position of the outer surface 411). The pressure-releasing groove 413 has a depth H, and the innermost third step portion 412c has a depth h, measured from the outer surface 411. The depth H is about 1.5 to 4 times (preferably 1.5 times) of the depth h. For example, if the depth h of the innermost third step portion 412c is 0.02 mm, the depth H of the pressure-releasing groove 413 is preferably 0.03 mm. During a molding process performed on a semiconductor package integrated with the heat dissipating structure 41, when a molding compound injected into a mold cavity of an encapsulation mold flows to the first, second and third step portions 412a, 412b and 412c of the stepped structure 412 and compresses air remaining at the stepped structure 412 (as shown in FIG. 6B), pressure caused by compressing the air can be rapidly released from the stepped structure 412 through the pressure-releasing groove 413, such that the compressed air is prevented from being squeezed into a seam between the heat dissipating structure and the encapsulation mold, thereby eliminating flashes of the molding compound and resin bleeding.

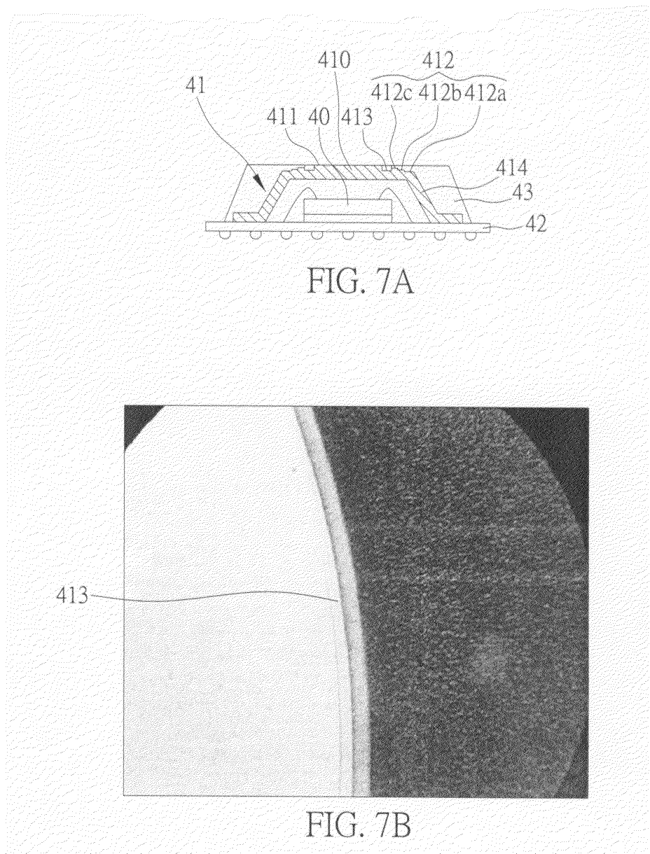

FIG. 7A is a cross-sectional view of a heat dissipating semiconductor package having the above heat dissipating structure in accordance with a first embodiment of the present invention.

The heat dissipating semiconductor package comprises a substrate 42, at least one semiconductor chip 40, and the heat dissipating structure 41. The semiconductor chip 40 is mounted on and electrically connected to the substrate 42. The semiconductor chip 40 can be electrically connected to the substrate 42 by bonding wires (as shown in FIG. 7A) or by a flip-chip technique. The heat dissipating structure 41 is mounted on the substrate 42. The heat dissipating structure 41 comprises a heat dissipating body 410 and a supporting portion 414 integrally formed with the heat dissipating body 410. The heat dissipating body 410 comprises an outer surface 411 exposed from an encapsulant 43 that encapsulates the semiconductor chip 40, a portion of the substrate 42, and a portion of the heat dissipating structure 41. A plurality of consecutive recessed step portions are formed on an edge of the outer surface 411 of the heat dissipating structure 41, and include a first step portion 412a, a second step portion 412b, and a third step portion 412c, which in such order are located at positions getting closer to a central position of the outer surface 411 and have decreasing depths measured from the outer surface 411. A pressure-releasing groove 413 is disposed adjacent to the innermost step portion (i.e. the third step portion 412c closest to the central position of the outer surface 411). The pressure-releasing groove 413 is deeper than the innermost third step portion 412c. The supporting portion 414 of the heat dissipating structure 41 is mounted to the substrate 42 and supports the heat dissipating body 410 above the semiconductor chip 40.

During a molding process, the outer surface 411 of the heat dissipating structure 41 directly abuts against a top wall of a mold cavity of an encapsulation mold (not shown). When a molding compound for forming the encapsulant 43 is injected into the mold cavity and flows to the first step portion 412a of the heat dissipating structure 41, the molding compound absorbs heat transferred from the encapsulation mold rapidly and thus its viscosity is increased, making the molding compound slow down its flowing speed. Then, the molding compound flows to the second step portion 412b and keeps absorbing the heat from the encapsulation mold. Since the second step portion 412b is shallower than the first step portion 412a, the space for accommodating the molding compound at second step portion 412b becomes smaller such that the molding compound absorbs the heat more rapidly and thus its flow further slows down. Similarly, the molding compound when reaching the third step portion 412c becomes more viscous and flows further slower. In the meantime, the flowing speed of the molding compound is sufficiently reduced. When air remaining at the step portions suffers increasing pressure as being compressed by the molding compound and flows to the pressure-releasing groove 413 that is adjacent to and deeper than the innermost third step portion 412c, the deeper pressure-releasing groove 413 can quickly release the pressure such that the air would not be squeezed into any seam between the heat dissipating structure 41 and the encapsulation mold. As a result, flashes of the molding compound and resin bleeding can be prevented.

FIG. 7B is a real partial top view of the heat dissipating structure 41 of the heat dissipating semiconductor package in accordance with the present invention. Since the pressure-releasing groove 413 of the heat dissipating structure rapidly releases the pressure suffered by the air at the step portions, the air would not be squeezed into any seam between the heat dissipating structure and the encapsulation mold, thereby eliminating flashes of the molding compound and resin bleeding as shown in FIG. 7B. By the above arrangement, since the molding compound does not flash to the outer surface 411 of the heat dissipating structure 41 during the molding process, it can ensure the planarity and cleanness and the heat dissipating area of the outer surface 411, making the outer surface 411 capable of being effectively attached to an external heat sink. Further due to no flashes of the molding compound, there is no need to perform any deflash process on the outer surface 411 of the heat dissipating structure 41 after the molding process, such that the fabrication cost is reduced and the product yield is improved. Moreover, the first step portion 412a, the second step portion 412b, the third step portion 412c and the pressure-releasing groove 413 together form a relatively long path that makes external moisture relatively difficult to invade and enter the semiconductor package, such that delamination caused by the invasion of moisture into the semiconductor package can be prevented and thus the reliability of the finished product is improved.

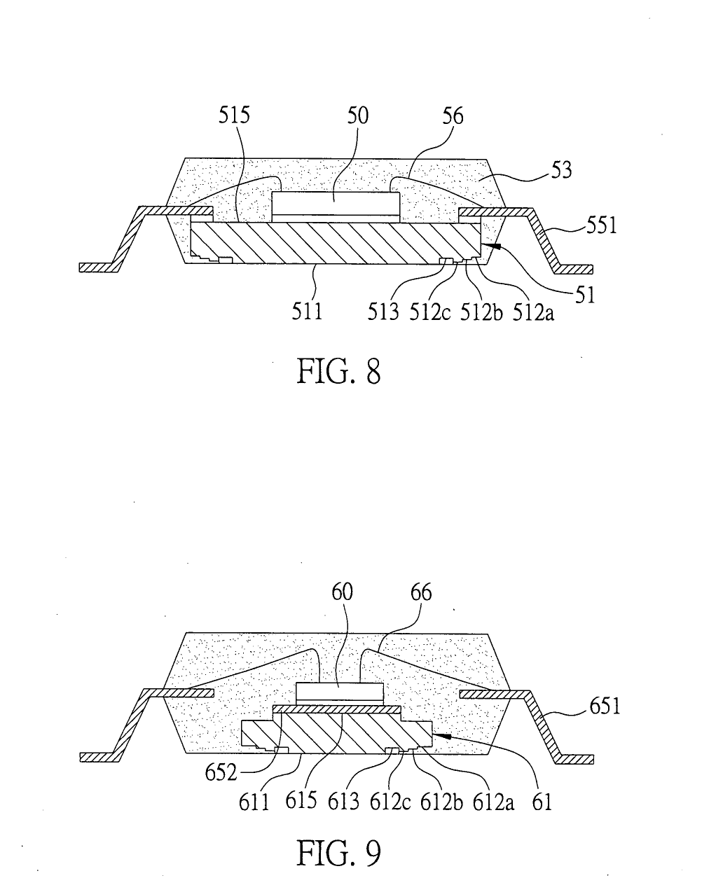

FIG. 8 is a cross-sectional view showing of a heat dissipating semiconductor package having the above heat dissipating structure in accordance with a second embodiment of the present invention, wherein same or similar components are represented by same or similar reference numerals as compared with the first embodiment and detailed descriptions thereof are omitted to allow the present invention to be more easily understood.

In the second embodiment, a semiconductor chip 50 of the heat dissipating semiconductor package is mounted on an inner surface 515 opposing to an outer surface 511 of a heat dissipating structure 51. A plurality of leads 551 are attached to a peripheral portion of the inner surface 515 of the heat dissipating structure 51. The semiconductor chip 50 is electrically connected through bonding wires 56 to positions of the leads 551 where the heat dissipating structure 51 supports, such that wire-bonding quality during a process of forming the bonding wires 56 can be assured. After the wire bonding process, the semiconductor chip 50, the bonding wires 56, portions of the leads 551 and a portion of the heat dissipating structure 51 are encapsulated by a molding compound that is cured to become an encapsulant 53, wherein the outer surface 511 of the heat dissipating structure 51 is exposed from the encapsulant 53 and is used to dissipate heat generated and transmitted from the semiconductor chip 50. Alternatively, a heat spreader (not shown) may further be mounted on the outer surface 511 of the heat dissipating structure 51 to facilitate effective heat dissipation.

Similarly to the arrangement of the first embodiment, consecutive recessed step portions, including a first step portion 512a, a second step portion 512b and a third step portion 512c, are also formed at an edge of the outer surface 511 of the heat dissipating structure 51, and a pressure-releasing groove 513 is located adjacent to the third step portion 512c. During a molding process of forming the encapsulant 53, the flowing speed of the molding compound is reduced by the first, second and third step portions 512a, 512b, 512c, and pressure suffered by air remaining at these step portions is released by the pressure-releasing groove 513, thereby preventing the molding compound from flashing to the outer surface 511 of the heat dissipating structure 51 and also eliminating resin bleeding.

FIG. 9 is a cross-sectional view of a heat dissipating semiconductor package in accordance with a third embodiment of the present invention.

In the third embodiment, the semiconductor package comprises a lead frame having a die pad 652 and a plurality of leads 651. A heat dissipating structure 61 is attached via its inner surface 615 to a bottom surface of the die pad 652. A semiconductor chip 60 is mounted on a top surface of the die pad 652 and is electrically connected to the leads 651 by bonding wires 66. As a result, heat generated by the semiconductor chip 60 is transmitted through the die pad 652 to the heat dissipating structure 61 and then is directly dissipated out of the semiconductor package via the outer surface 611 of the heat dissipating structure 61 or to another external heat spreader.

The semiconductor chip 60, the bonding wires 66, the die pad 652 of the lead frame, inner portions of the leads 651 and a portion of the heat dissipating structure 61 are encapsulated by an encapsulant 63 made of a molding compound, wherein the outer surface 611 of the heat dissipating structure 61 is exposed from the encapsulant 63. Consecutive recessed step portions, including a first step portion 612a, a second step portion 612b and a third step portion 612c, are formed at an edge of the outer surface 611 of the heat dissipating structure 61 and a pressure-releasing groove 613 is located adjacent to the third step portion 612c, which work together to effectively prevent flashes of the molding compound and resin bleeding to the outer surface 611.

Therefore, by the semiconductor package and the heat dissipating structure thereof according to the present invention, there are at least two consecutive recessed step portions formed at an edge of an outer surface of a heat dissipating body of the heat dissipating structure, wherein the step portions together form a stepped structure and have decreasing depths measured from the outer surface of the heat dissipating body. The closer the step portion to the central position of the outer surface, the smaller the depth of this step portion is. During a molding process, when a molding compound for forming an encapsulant flows to the step portions of the heat dissipating structure, the molding compound absorbs heat from an encapsulation mold rapidly due to the decreasing depths of the step portions, such that viscosity of the molding compound is increased and the flowing speed thereof is reduced. When the molding compound reaches the innermost step portion, its flowing speed is sufficiently reduced. A pressure-releasing groove is located next to and deeper than the innermost step portion, such that when the molding compound flows to the step portions and compresses air remaining at the step portions, the compressed air reaches the relatively deeper pressure-releasing groove where great pressure suffered by the air can be released rapidly, thereby not making the air squeezed into any seam between the heat dissipating structure and the encapsulation mold. As a result, flashes of the molding compound and resin bleeding are both prevented.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A heat dissipating structure for a semiconductor package, the heat dissipating structure comprising:
a heat dissipating body having an outer surface exposed from an encapsulant that encapsulates a semiconductor chip in the semiconductor package;
a plurality of consecutive recessed step portions formed at an edge of the outer surface of the heat dissipating body, and having decreasing depths in a manner that the closer a step portion to a central position of the outer surface of the heat dissipating body, the smaller the depth of this step portion is; and
a pressure-releasing groove disposed next to and deeper than an innermost one of the step portions which is closest to the central position of the outer surface of the heat dissipating body.

2. The heat dissipating structure of claim 1, wherein the pressure-releasing groove is 1.5 to 4 times deeper than the innermost one of the step portions.

3. The heat dissipating structure of claim 1, wherein the pressure-releasing groove is 1.5 times deeper than the innermost one of the step portions

4. The heat dissipating structure of claim 1, further comprising a supporting portion integrally formed with the heat dissipating body.

5. A heat dissipating semiconductor package comprising:
a substrate;
at least one semiconductor chip mounted on and electrically connected to the substrate; and
a heat dissipating structure mounted on the substrate, the heat dissipating structure comprising a heat dissipating body having an outer surface, and a supporting portion integrally formed with the heat dissipating body to hold the heat dissipating body above the semiconductor chip, the heat dissipating structure further comprising a plurality of consecutive recessed step portions and a pressure-releasing groove, wherein the outer surface is exposed from an encapsulant that encapsulates the semiconductor chip, a portion of the substrate and a portion of the heat dissipating structure, the step portions are formed at an edge of the outer surface and have decreasing depths in a manner that the closer a step portion to a central position of the outer surface of the heat dissipating body, the smaller the depth of this step portion is, and the pressure-releasing groove is disposed next to and deeper than an innermost one of the step portions which is closest to the central position of the outer surface.

6. The heat dissipating semiconductor package of claim 5, wherein the pressure-releasing groove is 1.5 to 4 times deeper than the innermost one of the step portions.

7. The heat dissipating semiconductor package of claim 5, wherein the pressure-releasing groove is 1.5 times deeper than the innermost one of the step portions.

8. The heat dissipating semiconductor package of claim 5, wherein the outer surface of the heat dissipating body abuts against a top wall of a mold cavity of an encapsulation mold in a process of forming the encapsulant.

9. The heat dissipating semiconductor package of claim 8, wherein a molding compound for forming the encapsulant flows to the step portions of the heat dissipating structure and absorbs heat from the encapsulation mold rapidly, such that viscosity of the molding compound is increased and a flowing speed thereof is reduced, and pressure suffered by air remaining at the step portions is released through the pressure-releasing groove.

10. A heat dissipating semiconductor package comprising:
at least one semiconductor chip;
a plurality of leads electrically connected to the semiconductor chip; and
a heat dissipating structure attached to the semiconductor chip, the heat dissipating structure comprising an outer surface, a plurality of consecutive recessed step portions and a pressure-releasing groove, wherein the outer surface is exposed from an encapsulant that encapsulates the semiconductor chip, a portion of the heat dissipating structure and portions of the leads, the steps portions are formed at an edge of the outer surface and have decreasing depths in a manner that the closer a step portion to a central position of the outer surface of the heat dissipating body, the smaller the depth of this step portion is, and the pressure-releasing groove is disposed next to and deeper than an innermost one of the step portions which is closest to the central position of the outer surface.

11. The heat dissipating semiconductor package of claim 10, wherein the semiconductor chip is attached to an inner surface opposing to the outer surface of the heat dissipating structure.

12. The heat dissipating semiconductor package of claim 11, wherein the leads are attached to a peripheral portion of the inner surface of the heat dissipating structure, and the semiconductor chip is electrically connected to the leads by bonding wires.

13. The heat dissipating semiconductor package of claim 10, further comprising a die pad disposed on an inner surface opposing to the outer surface of the heat dissipating structure.

14. The heat dissipating semiconductor package of claim 13, wherein the semiconductor chip is mounted on the die pad.

15. The heat dissipating semiconductor package of claim 10, further comprising an external heat spreader attached to the outer surface of the heat dissipating structure.

16. The heat dissipating semiconductor package of claim 10, wherein the pressure-releasing groove is 1.5 to 4 times deeper than the innermost one of the step portions.

17. The heat dissipating semiconductor package of claim 10, wherein the pressure-releasing groove is 1.5 times deeper than the innermost one of the step portions.

18. The heat dissipating semiconductor package of claim 10, wherein the outer surface of the heat dissipating structure abuts against a top wall of a mold cavity of an encapsulation mold in a process of forming the encapsulant.

19. The heat dissipating semiconductor package of claim 18, wherein a molding compound for forming the encapsulant flows to the step portions of the heat dissipating structure and absorbs heat from the encapsulation mold rapidly, such that viscosity of the molding compound is increased and a flowing speed thereof is reduced, and pressure suffered by air remaining at the step portions is released through the pressure-releasing groove.
